(19) United States
(12) Patent Application Publication
(10) Pub. No.: US 2012/0187336 A1
(43) Pub. Date: Jul. 26, 2012

(54) CONDITIONING COMPOSITIONS FOR SOLAR CELLS

(75) Inventors: Shahriar Naghshineh, Allentown, PA (US); Ewa Oldak, Fountain Hill, PA (US); George Schwartzkopf, Washington, NJ (US)

(73) Assignee: SURFACE CHEMISTRY DISCOVERIES, INC., Bethlehem, PA (US)

(21) Appl. No.: 13/354,423

(22) Filed: Jan. 20, 2012

Related U.S. Application Data
(60) Provisional application No. 61/461,596, filed on Jan. 20, 2011.

(51) Int. Cl. C09K 13/02; H01L 31/18; B08B 3/08; B08B 3/12; C11D 7/60; C09K 13/00

(52) U.S. Cl. 252/79.5; 510/175; 252/79.1; 134/2; 134/1; 438/71; 257/E31.13

(57) ABSTRACT

Method of using improved compositions for conditioning silicon surfaces during the manufacture of photovoltaic devices. Used for removing particles, organic contamination, and unwanted metals from these surfaces. Also used for removing a thin layer of silicon as required for damage removal or texturing. These conditioning and surface preparation compositions comprise one or more water soluble strongly basic components capable of producing a pH greater than 10, one or more water soluble organic amines, one or more chelating agents, and water.

### CROSS REFERENCE TO RELATED APPLICATIONS

This application claims the benefit of U.S. Provisional Application No. 61/461,596, filed Jan. 20, 2011, the entire contents which are incorporated herein by reference as if fully set forth.

### BACKGROUND OF THE INVENTION

The present invention concerns the conditioning of silicon surfaces during the course of manufacturing photovoltaic devices, specifically to remove particles, organic contamination, unwanted metals or, alternatively, to effect removal of a desired thickness of silicon, from a silicon surface.

The fabrication of photovoltaic cells generally requires a process step during which the silicon surface is “textured” to reduce the reflectivity of the surface thereby increasing the efficiency of the resulting solar cell. Typically such texturing is accomplished by treating mono-crystalline silicon substrates with a strongly alkaline aqueous base containing about three percent of isopropyl alcohol at an operating temperature of about 80° C. Alternatively, multi-crystalline silicon substrates are textured using strongly acidic mixtures.

Silicon wafers are routinely conditioned before texturing to remove organic contamination such as cutting oils and fingerprints. This contamination occurs during a previous process step during which the silicon is sliced into thin wafers using a wire cutting saw. This sawing step may also contaminate the surface with particulate matter and unwanted metals.

Transition metals are known to be detrimental to the quality of the resulting photovoltaic cells. More specifically, traces of iron, nickel, chromium, copper and zinc are known to degrade minority carrier lifetime. Photovoltaic efficiency is directly correlated to minority carrier lifetime.

The surfaces of silicon wafers may also suffer considerable physical damage as a result of the sawing procedure. This frequently necessitates an additional process step referred to as “saw damage removal.”

“Standard Clean 1” (SC-1), a mixture of one part of concentrated ammonium hydroxide, one part of 30% hydrogen peroxide, and five parts of water, at an operating temperature of about 80° C., is commonly used to condition silicon before texturing. Mixing SC-1 requires considerable care since concentrated ammonium hydroxide continuously evolves toxic ammonia gas. Both ammonium hydroxide and hydrogen peroxide present skin contact hazards and hot SC-1 occasionally evolves oxygen suddenly and boils over. After texturing, the wafers may be treated with additional aggressive compositions, typically containing hydrofluoric acid, another very hazardous substance. Both SC-1 and dilute hydrofluoric acid are known to deposit transition metals onto silicon surfaces.

The compositions of this invention are effective in highly dilute solution and may be applied both before and after wafer texturing as alternatives to the aggressive solutions mentioned above. The conditioning temperature is routinely below 60° C. In addition to removing organic impurities from the surface, these compositions chelate and thereby remove a variety of metal ion contaminants, most notably, transition metal cations.

Joo, U.S. Pat. Appl. No. 2008/0202551, discloses a multistep method for removing polyethylene glycol or polypropylene glycol cutting fluids from freshly sliced solar cell substrates. The substrates are first sprayed with deionized water while applying ultrasonic energy, followed by cleaning with a mixture containing 10 to 50 weight % of an alkali surfactant and 20 weight % of sodium hydroxide. Finally the wafers are etched with a mixture containing 5 to 80 weight percent of sodium hydroxide and 10 to 13 weight % of hydrogen peroxide. Clearly an alternative method for conditioning these wafers prior to texturing would be advantageous. A single-step method that consumes fewer chemical components would be best.

Wijekoon et al., U.S. Pat. Appl. No. 2009/0280597, discloses a surface cleaning and texturing process for crystalline solar cells. Various pre-texturing treatments are recommended including aqueous hydrogen fluoride, hydrofluoric acid and nitric acid mixtures, SC-1 cleaning solution (described above), and SC-2 cleaning solution (a mixture of hydrochloric acid, hydrogen peroxide and water). Post-texturing treatments are also claimed, including ozonated water followed by hydrofluoric acid or mixtures of hydrofluoric acid and hydrochloric acid. Methods for conditioning these wafers, before and after texturing, without the use of such hazardous chemicals would be desirable.

Reinhardt et al., U.S. Pat. Appl. No. 2011/0079520, discloses post-texturing cleaning methods for photovoltaic silicon substrates that allow for the recycling of the rinsing baths to various upstream rinse steps. The pre-texturing step can include a dilute SC-1 rinse followed by a dilute hydrochloric acid rinse, with or without added hydrofluoric acid. The post-texturing treatments include ozonated water followed by dilute hydrofluoric acid with or without added hydrochloric acid, then dilute SC-1 or an alternative alkaline treatment, or another ozonated water treatment. Again, the use of less hazardous chemicals would be advantageous.

Treichel et al, Photovoltaics International, 12^{th} Edition, May 2011, p 81ff; also in Technical Proceedings of the 2010 Clean Technology Conference, Nanotech 2010 Vol. 3, and in Technical Abstracts of the 220^{th} ECS Meeting and Electrochemical Energy Summit, October 2011, discuss the use of an unnamed “biodegradable complexing agent” for transition metal removal during certain photovoltaic processing steps. The Treichel, et al work suggests that this new complexing agent must be added to both the hydrofluoric acid and the deionized water used for post-texturing and post-phosphorous silicate glass removal cleaning steps to be useful. This multiple use of a new, no doubt expensive, complexing agent may be disadvantageous. It is likely that its toxicology has not yet been fully investigated, and regulatory aspects for its use, for example TOSCA registration, may not be complete.

Those concerned with the development of surface cleaning and preparation technology have continuously sought techniques that avoid the use of hazardous materials, e.g., hydrochloric acid, hydrofluoric acid, nitric acid, and other hazardous and environmentally unacceptable components.

### SUMMARY OF THE INVENTION

In accordance with the present invention, methods and compositions are provided for removing particles and organic contamination from silicon surfaces present during the manufacture of photovoltaic devices. Metal ions, particularly transition metal ions, present on or beneath such surfaces are also effectively removed. The cleaning and surface preparation compositions comprise one or more water soluble strongly basic components capable of producing a pH greater than 10, one or more water soluble organic amines, one or more chelating agents, and water. The method of the invention comprises contacting said surfaces with said composition with optional heating and/or the application of sonic energy.

The compositions of the present invention have very high water content resulting in low cost compositions that may be safely transported and dispensed, and the safe disposal of which may consist of discharge to an appropriate industrial drain without any additional pretreatment. All of the components of the compositions of the present invention have well known toxicology and have been properly registered for industrial use.

Accordingly, several advantages of the present invention are that these compositions:

(a) have an extremely high water concentration resulting in low cost and negligible environmental impact

(b) allow short processing times

(c) do not contain hydrofluoric acid or salts thereof.

(d) do not contain solvents classified as hazardous air pollutants (HAPs), such as glycol ethers

(e) require only deionized water rinsing

(f) allow the use of process water containing traces of transition metals

(g) will not foam, and

(h) have a long bath life.

The ability of these compositions, which may contain greater than 99.9% water, to remove organic contamination is unexpected. Typically solvent mixtures are used for this purpose.

### BRIEF DESCRIPTION OF THE DRAWINGS

FIG. 1A is a photograph of a piece of monocrystalline silicon which was intentionally contaminated with a fingerprint taken at 2× magnification.

FIG. 1B is a photograph of the same piece of monocrystalline silicon after removal of the fingerprint with one of the compositions of the present invention taken at 2× magnification.

FIG. 2A is an energy-dispersive X-ray (EDX) spectrum of a piece of monocrystalline silicon after texturing with a potassium hydroxide solution without any further treatment.

FIG. 2B is an EDX spectrum of a piece of monocrystalline silicon after texturing with a potassium hydroxide solution and rinsing with deionized water.

FIG. 2C is an EDX spectrum of a piece of monocrystalline silicon after texturing with a potassium hydroxide solution, rinsing with deionized water, and treatment with one of the compositions of the present invention.

FIG. 3A is a scanning electron microscopy SEM photomicrograph of a piece of multicrystalline silicon which was intentionally contaminated with cutting slurry then cleaned ultrasonically with deionized water at 25,000× magnification.

FIG. 3B is a SEM photomicrograph of a piece of multicrystalline silicon which was intentionally contaminated with cutting slurry then cleaned ultrasonically with one of the compositions of the present invention diluted 20:1 with deionized water at 25,000× magnification.

FIG. 3C is a SEM photomicrograph of a piece of multicrystalline silicon which was intentionally contaminated with cutting slurry then cleaned ultrasonically with one of the compositions of the present invention diluted 30:1 with deionized water at 25,000× magnification.

FIG. 3D is a SEM photomicrograph of a piece of multicrystalline silicon which was intentionally contaminated with cutting slurry then cleaned ultrasonically with one of the compositions of the present invention diluted 50:1 with deionized water at 25,000× magnification.

FIG. 4A is a partial K-alpha X-ray photoelectron (XPS) spectrum of a sample of photovoltaic silicon that was contaminated with silver during commercial processing.

FIG. 4B is an XPS spectrum of a sample of photovoltaic silicon that was contaminated with silver as before and treated with one of the compositions of the present invention.

FIG. 5A is an optical photomicrograph of a piece of monocrystalline silicon typically used to manufacture photovoltaic devices at 400× magnification.

FIG. 5B is an optical photomicrograph of a similar piece of monocrystalline silicon after texturing with one of the compositions of the present invention at 400× magnification.

### DETAILED DESCRIPTION OF THE INVENTION

The present invention provides new aqueous compositions for conditioning and cleaning silicon surfaces present during the manufacture of photovoltaic devices that comprise one or more water soluble strongly basic components capable of producing a pH greater than 10, one or more water soluble organic amines, one or more chelating agents, and water. These compositions may be prepared by blending or mixing components of the composition according to any method known in the art.

Preferably, these compositions comprise from about 0.001% to about 5% by weight of water soluble strongly basic components, from about 0.002% to about 15% by weight of water soluble organic amines, from 0.001% to about 4% by weight of chelating agents, and the balance of water and where the composition has a pH from about 10 to 13. More preferably, these compositions comprise from about 0.01% to about 2.5% by weight of water soluble strongly basic components, from about 0.05% to about 10% by weight of water soluble organic amines, from about 0.01% to about 2% by weight of chelating agents, and the balance of water and where the composition has a pH from about 10 to 13.

The water soluble strongly basic components may comprise any number of bases. Preferably, the water soluble strong base is a quaternary ammonium hydroxide, such as tetraalkyl ammonium hydroxides (including hydroxyl- and alkoxy-containing alkyl groups generally from 1 to 4 carbon atoms in the alkyl or alkoxy group) or a metal hydroxide such as potassium or sodium hydroxide. The most preferable of these bases are tetramethyl ammonium hydroxide, tetraethyl ammonium hydroxide, and potassium hydroxide. Examples of other usable quaternary ammonium hydroxides include: benzyltrimethyl ammonium hydroxide, trimethyl-2-hydroxyethyl ammonium hydroxide (choline), trimethyl-3-hydroxypropyl ammonium hydroxide, trimethyl-3-hydroxybutyl ammonium hydroxide, trimethyl-4-hydroxybutyl ammonium hydroxide, triethyl-2-hydroxyethyl ammonium hydroxide, tripropyl-2-hydroxyethyl ammonium hydroxide, tributyl-2-hydroxyethyl ammonium hydroxide, dimethylethyl-2-hydroxyethyl ammonium hydroxide, dimethyldi(2-hydroxyethyl) ammonium hydroxide, monomethyltri(2-hydroxyethyl) ammonium hydroxide, tetrabutyl ammonium hydroxide, tetrapropyl ammonium hydroxide, monomethyltriethyl ammonium hydroxide, monomethyltripropyl ammonium hydroxide, monomethyltributyl ammonium hydroxide, monoethyltrimethyl ammonium hydroxide, monoethyltributyl ammonium hydroxide, and the like and mixtures thereof.

The water soluble organic amine components may comprise any number of amines. Preferably, the water soluble organic amine is an alkanolamine. The most preferable of these amines are 2-aminoethanol and 2-dimethylaminoethanol. Examples of other usable water soluble organic amines include: alkanolamines such as 1-amino-2-propanol, 1-amino-3-propanol, 2-(2-aminoethoxy)ethanol, 2-methylaminoethanol, 2-(2-aminoethylamino)ethanol, 4-(3-aminopropyl)morpholine, diethanolamine, triethanolamine, and the like, and other strong organic bases such as guanidine, 1,3-pentanediamine, 4-aminomethyl-1,8-octanediamine, 2-aminoethylpiperazine, 2-(2-aminoethylamino)ethylamine, 1,2-diaminocyclohexane, tris(2-aminoethyl)amine, and 2-methyl-1,5-pentanediamine.

The chelating components may comprise any number of chelating agents used to increase the capacity of the formulation to retain metals in solution and to enhance the dissolution of metallic residues on or beneath the silicon surface. Typical examples of water soluble chelating agents useful for this purpose, known to those skilled in the art, include the following organic acids and their isomers and salts; ethylenediaminetetraacetic acid (EDTA), butylenediaminetetraacetic acid, 1,2-diaminocyclohexane-N,N,N′,N′-tetraacetic acid (CyDTA), diethylenetriaminepentaacetic acid (DETPA), ethylenediaminetetraproprionic acid, (hydroxyl)ethylenediaminetriacetic acid (HEDTA), N,N,N′,N′-ethylenediaminetetra(methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrilotriacetic acid (NTA), citric acid, tartaric acid, gluconic acid, saccharic acid, glyceric acid, phthalic acid, maleic acid, mandelic acid, malonic acid, lactic acid, salicylic acid, and cystine. Preferred chelating agents are aminocarboxylic acids such as EDTA and CyDTA. Chelating agents of this class have a high affinity for iron and other transition metals. This affinity is more pronounced at pH>10. The presence of transition metals is known to have a deleterious effect on minority carrier lifetime thus may decrease solar cell efficiency. The use of chelating agents in the present invention facilitates the removal of these metals from the silicon giving solar cells with improved characteristics.

In one aspect the present invention is a conditioning solution for removing contaminants that remain on the silicon substrates after wire saw cutting. These contaminants include cutting oils, fingerprints, particles, and metal cations. This composition consists of 0.01 to 2.5% by weight water soluble strong base, 0.05 to 10% by weight alkanolamine, 0.01 to 2% by weight chelating agent, the balance water. Preferably, the pH of the solution is greater than 10.

In another aspect the present invention is a conditioning solution for removing the top layer of silicon that has been damaged by wire saw cutting. This composition consists of 0.02 to 2.5% by weight water soluble strong base, 0.1 to 9% by weight alkanolamine, 0.02 to 2% by weight chelating agent, the balance water. Preferably, the pH of the solution is greater than 10.

In yet another aspect the present invention is a conditioning solution for texturing the silicon wafer surface to reduce unwanted reflectivity. This composition consists of 0.03 to 2.5% by weight water soluble strong base, 0.2 to 9% by weight alkanolamine, 0.03 to 2% by weight chelating agent, the balance water. Preferably, the pH of the solution is greater than 10.

In still another embodiment the present invention is a conditioning solution for removing contaminants that remain on the silicon substrates after texturing in an alkaline bath. These contaminants include transition metal impurities that are deposited from the strongly alkaline texturing medium. This composition consists of 0.01 to 2.5% by weight water soluble strong base, 0.05 to 9% by weight alkanolamine, 0.01 to 2% by weight chelating agent, the balance water. Preferably, the pH of the solution is greater than 10.

If the textured silicon layer is very thin and a very low silicon etch rate is required, an additional embodiment is used wherein the concentration of the alkanolamine is reduced to 0.002% by weight or lower while maintaining the water soluble strong base at 0.01 to 2.5% by weight, the chelating agent at 0.01 to 2% by weight, the balance water. Preferably, the pH of the solution is greater than 10.

Alternatively, an additional embodiment may also be used to achieve extremely low silicon etch rates. This composition consists of 0.01 to 2.5% by weight water soluble strong base, 0.05 to 9% by weight alkanolamine, 0.01 to 2% by weight chelating agent, 0.01 to 2% by weight of potassium or sodium silicate, the balance water. Preferably, the pH of the solution is greater than 10.

In another embodiment of the present invention, these compositions are used to condition silicon surfaces subsequent to phosphorous doping. Silicon cleaned in this way yields photovoltaic cells with higher efficiency.

These compositions may be used at a wide range of concentrations to condition various silicon surfaces during the manufacture of photovoltaic devices. These silicon surfaces include both monocrystalline and multicrystalline silicon surfaces. Treatment with these compositions effectively removes undesirable surface contaminants including cutting oils, fingerprints, particles, and metal cations. Treatment with these compositions at higher temperature and for longer times can also be used to remove a damaged layer of silicon or to texture the silicon which desirably reduces reflectivity.

When used for conditioning silicon surfaces, the surface is exposed to those compositions for a time and at a temperature sufficient to remove unwanted contaminates from the substrate surface or, alternatively, to effect removal of a desired thickness of silicon, rinsed with water, and dried. The substrate can then be used for the next manufacturing step ultimately resulting in the finished photovoltaic device.

Preferably the method uses a bath or spray application to expose the substrate to the composition. Bath or spray cleaning times are generally 1 minute to 60 minutes. Bath or spray cleaning temperatures are generally 10° C. to 85° C., preferably 20° C. to 80° C. Application of ultrasonic energy may be useful, especially if the substrate is heavily contaminated with particulate matter.

If required, the rinse times are generally 10 seconds to 5 minutes at room temperature, preferably 30 seconds to 2 minutes at room temperature. Preferably de-ionized water is used to rinse the substrates although the use of an intermediate 2-propanol rinse may also be useful.

If required, drying the substrates can be accomplished using any combination of air-evaporation, heat, spinning, pressurized gas, or Marangoni effect driers. The preferred drying technique is spinning under a filtered inert gas flow, such as nitrogen, for a period of time until the wafer substrate is dry.

Concentrates of these compositions may readily be prepared by reducing the percentage of water stated in the foregoing specifications. The resulting concentrates can later be diluted with an amount of water necessary to produce the desired effective cleaning compositions.

### EXAMPLES

The following examples illustrate specific embodiments of the invention described in this document. As would be apparent to skilled artisans, various changes and modifications are possible and are contemplated within the scope of the invention described.

The components listed in Table I were combined with stirring to give each of the fifteen homogeneous compositions.

TABLE I

| Composition | Formulation |
|---|---|
| 1 | 9.0 g 2-Aminoethanol (9.0%) |
| | 2.5 g Tetramethylammonium hydroxide (2.5%) |
| | 2.0 g Ethylenediaminetetraacetic acid (2.0%) |
| | 86.5 g water (86.5%) |
| 2 | 9.0 g 2-Aminoethanol (9.0%) |
| | 2.0 g Tetraethylammonium hydroxide (2.0%) |
| | 1.0 g Ethylenediaminetetraacetic acid (1.0%) |
| | 88.0 g water (88.0%) |
| 3 | 4.5 g 2-Aminoethanol (4.5%) |
| | 2.0 g Tetraethylammonium hydroxide (2.0%) |
| | 1.25 g 1,2-Cyclohexanediaminetetraacetic acid (1.25%) |
| | 92.2 g water (92.2%) |
| 4 | 9.0 g 2-Aminoethanol (9.0%) |
| | 1.25 g Tetramethylammonium hydroxide (1.25%) |
| | 1.0 g Ethylenediaminetetraacetic acid (1.0%) |
| | 88.8 g water (88.8%) |
| 5 | 2.6 g 2-Aminoethanol (2.6%) |
| | 1.25 g Tetramethylammonium hydroxide (1.25%) |
| | 1.0 g Ethylenediaminetetraacetic acid (1.0%) |
| | 95.2 g water (95.2%) |
| 6 | 9.0 g 2-Aminoethanol (9.0%) |
| | 0.77 g Potassium hydroxide (0.77%) |
| | 1.25 g 1,2-Cyclohexanediaminetetraacetic acid (1.25%) |
| | 89.0 g water (89.0%) |
| 7 | 9.0 g 2-Aminoethanol (9.0%) |
| | 1.25 g Tetramethylammonium hydroxide (1.25%) |
| | 1.25 g 1,2-Cyclohexanediaminetetraacetic acid (1.25%) |
| | 88.5 g water (88.5%) |
| 8 | 9.0 g 2-Aminoethanol (9.0%) |
| | 0.77 g Potassium hydroxide (0.77%) |
| | 1.0 g Ethylenediaminetetraacetic acid (1.0%) |
| | 89.2 g water (89.2%) |
| 9 | 9.0 g 2-Aminoethanol (9.0%) |
| | 2.5 g Tetramethylammonium hydroxide (2.5%) |
| | 2.5 g Ethylenediaminetetraacetic acid (2.5%) |
| | 86.0 g water (86.0%) |
| 10 | 8.9 g 2-Aminoethanol (8.9%) |
| | 2.5 g Tetramethylammonium hydroxide (2.5%) |
| | 3.0 g Ethylenediaminetetraacetic acid (3.0%) |
| | 85.6 g water (85.6%) |
| 11 | 8.8 g 2-Aminoethanol (8.8%) |
| | 2.4 g Tetramethylammonium hydroxide (2.4%) |
| | 4.0 g Ethylenediaminetetraacetic acid (4.0%) |
| | 84.8 g water (84.8%) |
| 12 | 4.5 g 2-Aminoethanol (4.5%) |
| | 2.5 g Tetramethylammonium hydroxide (2.5%) |
| | 2.0 g Ethylenediaminetetraacetic acid (2.0%) |
| | 91.0 g water (91.0%) |
| 13 | 2.5 g Tetramethylammonium hydroxide (2.5%) |
| | 2.0 g Ethylenediaminetetraacetic acid (2.0%) |
| | 95.5 g water (95.5%) |
| 14 | 1.0 g 2-Aminoethanol (1.0%) |
| | 2.5 g Tetramethylammonium hydroxide (2.5%) |
| | 2.0 g Ethylenediaminetetraacetic acid (2.0%) |
| | 94.5 g water (94.5%) |
| 15 | 0.1 g 2-Aminoethanol (0.1%) |
| | 2.5 g Tetramethylammonium hydroxide (2.5%) |
| | 2.0 g Ethylenediaminetetraacetic acid (2.0%) |
| | 95.4 g water (95.4%) |

### Example 1

### Comparison of Composition 1 to Standard SC-1 Clean

SC-1 was prepared by mixing five parts of deionized water, one part of 30% aqueous ammonium hydroxide, and one part of 30% aqueous hydrogen peroxide. This SC-1 mixture was compared to Composition 1 as a pre-texturing conditioning composition for mono-crystalline silicon.

Texturing was achieved by treating a silicon wafer sample with a stirred 3% aqueous potassium hydroxide solution containing 0.2% of a surfactant. The wafer samples had been previously left unconditioned, or conditioned with either SC-1 or dilute Composition 1 at 60-75° C. for four to ten minutes. The texturing process optimally yields complete coverage of the silicon surface with pyramidal structures resulting from the selective etching of Si[100] and Si[111] crystal faces. Texture coverage was evaluated by optical microscopy with a rating of 1=unsatisfactory surface coverage and a rating of 4=100% coverage. Silicon loss was calculated from the weight loss of the silicon wafer sample occurring during conditioning and texturing steps.

TABLE II

| | | Results | |
|---|---|---|---|
| Conditioning | | Texture | Si Loss, |
| Treatment | Texturing conditions | Coverage | μm/side |
| None | 80° C./25 min | 2 | 9.8 |
| SC-1 | 80° C./25 min | 1 | 11.1 |
| Composition 1 diluted | 80° C./25 min | 3 | 10.0 |
| 40:1 with water | | | |

As indicated in Table II, diluted Composition 1 gave superior texture coverage with acceptable silicon loss.

### Example 2

### Removal of Fingerprints from Monocrystalline Silicon

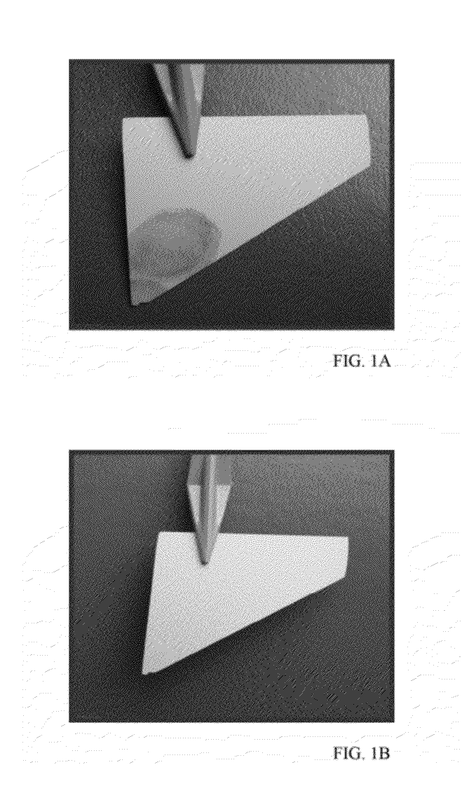

The silicon substrates used for the manufacture of photovoltaic cells must be free of fingerprints and other organic contamination. A piece of monocrystalline silicon was intentionally contaminated with a fingerprint as shown in FIG. 1A. Using a beaker and magnetic stirrer, this contaminated wafer piece was treated for one minute at room temperature with Composition 1 diluted 40:1 with water, while stirring at 400 rpm. This treatment completely removed the fingerprint as shown in FIG. 1B.

Heavier fingerprints were prepared by first touching the finger to petroleum jelly then pressing it onto a piece of monocrystalline silicon. Using a beaker and magnetic stirrer, a contaminated wafer piece of this type was treated for 60 minutes at room temperature with Composition 1 diluted 50:1 with water, while stirring at 400 rpm. This treatment completely removed the fingerprint. Additional Compositions 2, 3, 4, and 5 also removed a heavy fingerprint under the same conditions.

### Example 3

### Removal of Organic Contamination after Texturing

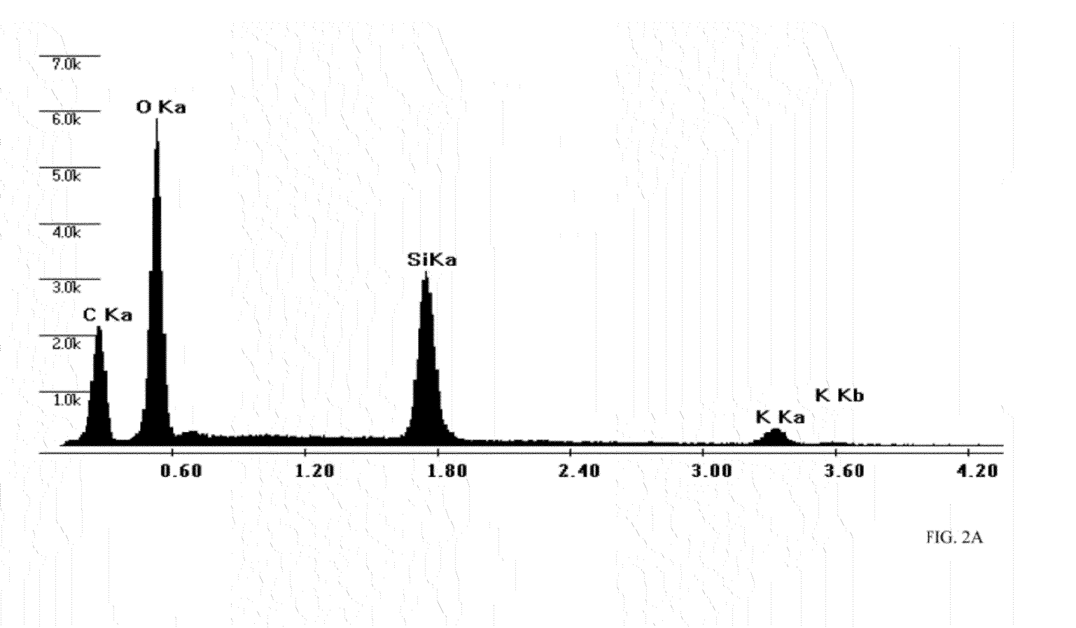

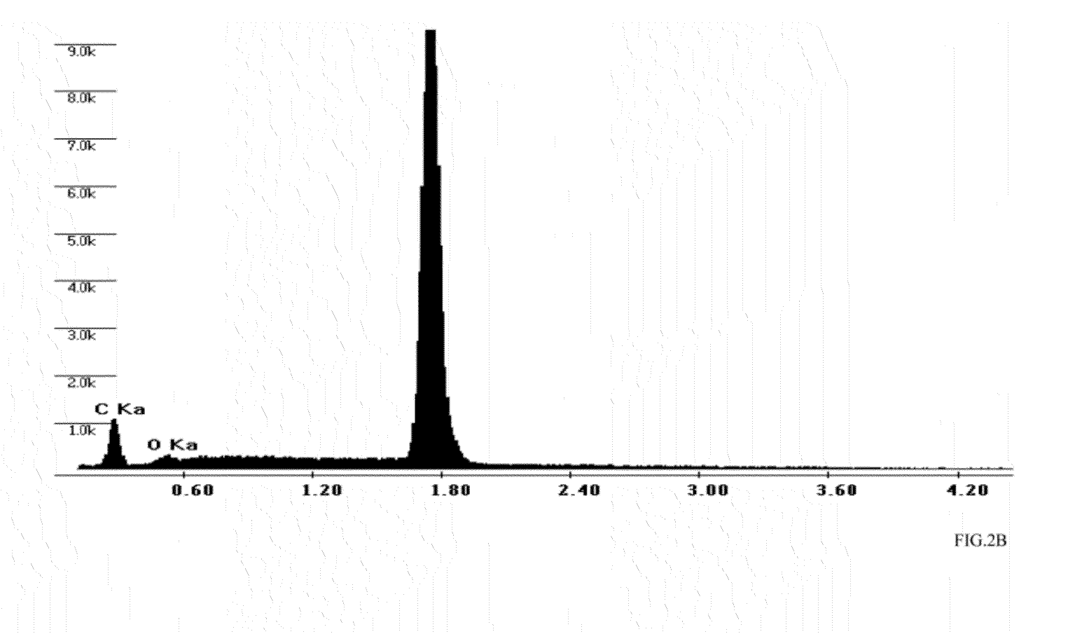

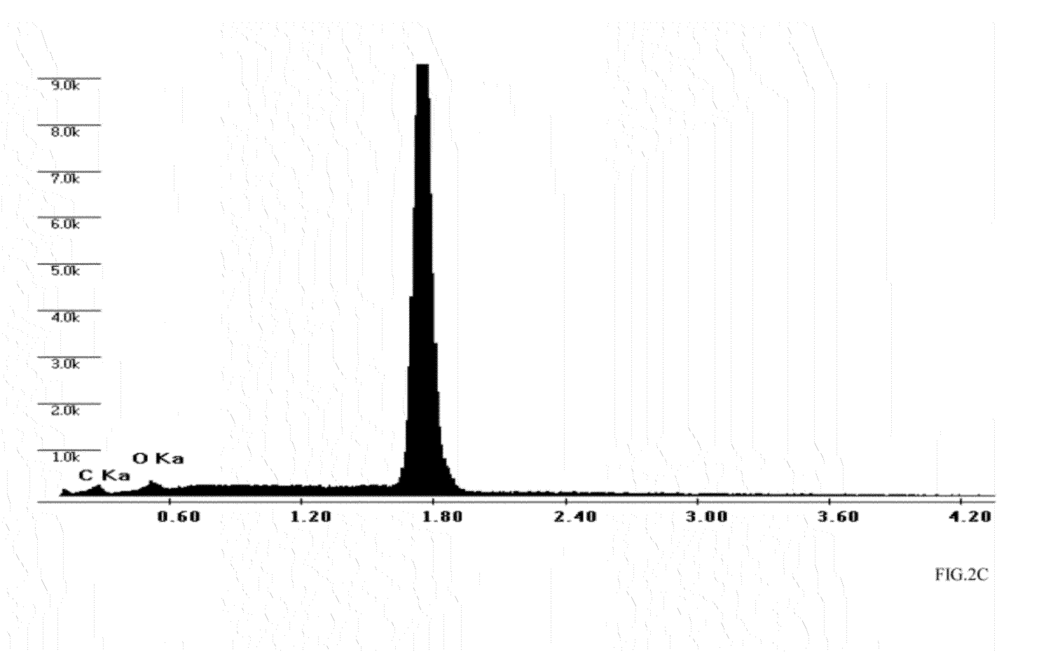

Silicon wafer pieces were textured by treating with stirred 3% aqueous potassium hydroxide containing 0.2% of a surfactant. The surfaces of representative wafer pieces were analyzed using energy-dispersive X-ray spectroscopy (EDX). Analysis before any rinsing gave the spectrum shown in FIG. 2A. In addition to the expected silicon peak, strong elemental peaks were observed for carbon, oxygen and potassium. The potassium and oxygen peaks indicate the presence of potassium hydroxide while the carbon peak suggests contamination by organic compounds. Rinsing with water gave the spectrum shown in FIG. 2B which shows that any residual potassium hydroxide has been rinsed off. Additional rinsing with Composition 1 diluted 40:1 with water for one minute at 30° C. gave the spectrum shown in FIG. 2C which shows very little remaining carbon contamination.

### Example 4

### Removal of Cutting Slurry from Multicrystalline Silicon Before Texturing

The silicon wafer substrates used to manufacture photovoltaic cells are cut from large ingots using a wire cutting technique utilizing an abrasive cutting slurry. Particles of this slurry are advantageously removed from the silicon surface before proceeding to the texturing step.

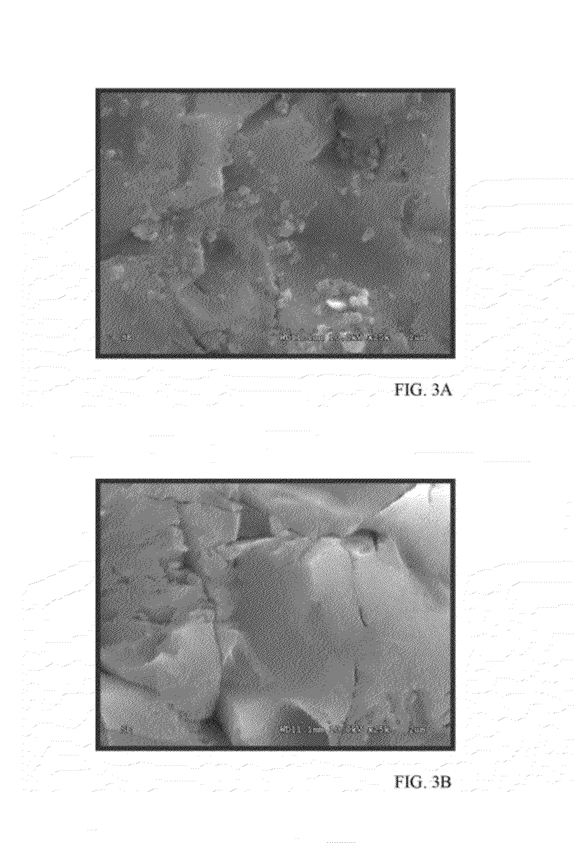

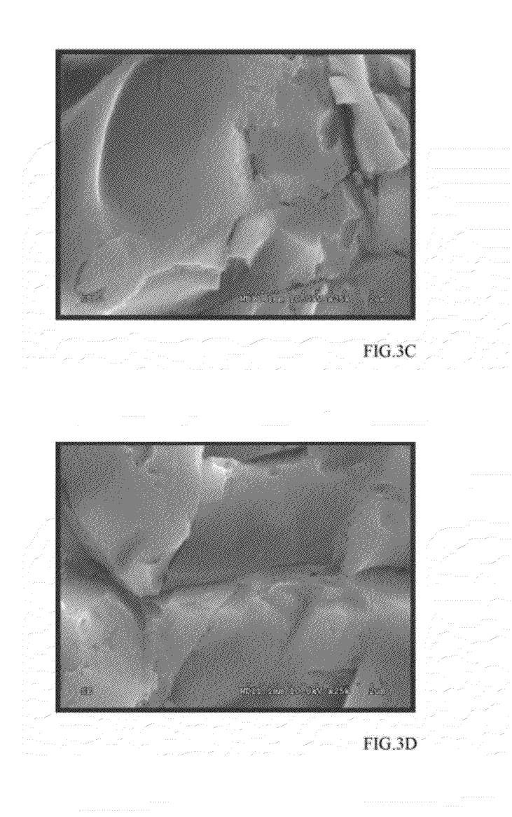

Pieces of multicrystalline silicon were contaminated with cutting slurry by dipping into 10% slurry for 10 seconds then drying at 85° C. for 24 hours. These contaminated samples were cleaned ultrasonically at about 40 kHz with water or various dilutions of Composition 1. The treatment conditions were 60° C. for 4 minutes. FIG. 3A is a SEM micrograph (25,000× magnification) obtained after cleaning with water alone. Considerable particulate contamination remained. FIG. 3B was obtained after cleaning with Composition 1 diluted 20:1 with water. FIG. 3C was obtained after cleaning with Composition 1 diluted 30:1 with water. FIG. 3D was obtained after cleaning with Composition 1 diluted 50:1 with water. All of the wafer pieces treated with diluted Composition 1 were particle-free.

### Example 5

### Silicon Etch Rates for Various Crystallographic Orientations

Silicon etch rates were calculated from the weight loss of silicon wafer samples occurring during treatments with Composition 1 diluted 100:1 with water:

TABLE III

| Silicon | | |
|---|---|---|
| Crystallographic | Treatment | Etch Rate |
| Orientation | Temperature | (μm/minute) |
| [100] | 40° C. | 0.022 |
| [111] | 40° C. | 0.012 |
| Multicrystalline | 40° C. | 0.019 |

The data in Table III shows that etch rates were all in an acceptable range. Even several minutes of treatment would only give <0.1 μm of silicon loss, insignificant when compared to the 10 μm loss that normally accompanies texturing.

### Example 6

### Silicon Loss During Wafer Conditioning

Compositions of the present invention are used to condition photovoltaic silicon substrates before and/or after alkaline texturing. It is desirable that the total silicon loss during conditioning and texturing treatments is about 10 μm per side and that the loss during the non-texturing, i.e., the conditioning, treatments is very low. Typically conditioning is conducted at 30-70° C. for less than ten minutes.

Unpolished silicon [100] wafer pieces, typical of those used for manufacturing photovoltaic devices, were cleaned with deionized water followed by 2-propanol, dried, and weighed. These pieces were then conditioned using various dilutions of Composition 1 at a selection of temperatures and treatment times while agitating with a magnetic stir bar at about 200 rpm. After conditioning, the silicon pieces were removed, again rinsed with deionized water and 2-propanol, dried and reweighed. Weight loss was converted to thickness loss using the equation:

$$Thickness loss ( μ m \text{/} side ) = \frac{1000 \times weight loss ( in gm ) \times starting thickness ( in mm )}{2 \times starting weight ( in gm )}$$

The results shown in Table IV demonstrate that a multiplicity of conditioning times and temperatures result in very little silicon loss during the actual conditioning treatment. The silicon loss observed during conditioning is much less than the ten micron per side loss that desirably occurs during alkaline texturing. Thus the goal stated above of conditioning with very low silicon loss can be achieved using a variety of temperature and time conditions.

TABLE IV

| | Conditioning | Conditioning | |
|---|---|---|---|
| Dilution Factor | Time | Temperature | Silicon Loss |
| Water:Composition 1 | (minutes) | (° C.) | (μm/side) |
| 40:1 | 1 | 30 | <0.005 |
| 60:1 | 1 | 30 | <0.005 |
| 80:1 | 1 | 30 | <0.005 |
| 40:1 | 1 | 50 | <0.005 |
| 60:1 | 1 | 50 | 0.008 |
| 80:1 | 1 | 50 | 0.007 |
| 60:1 | 5 | 30 | <0.005 |
| 40:1 | 5 | 55 | <0.005 |
| 60:1 | 10 | 30 | <0.005 |
| 60:1 | 20 | 30 | <0.005 |
| 40:1 | 30 | 40 | 0.04 |
| 60:1 | 30 | 30 | 0.02 |
| 80:1 | 30 | 50 | <0.005 |

### Example 7

### Silicon Loss During Conditioning with Alternate Compositions

Alternate compositions 4, 6, 7, and 8 were used for similar conditioning treatments and also resulted in very low silicon loss as detailed in Table V.

TABLE V

| | | | | Silicon |
|---|---|---|---|---|
| | | Conditioning | Conditioning | Loss |
| Alternate | Dilution Factor | Time | Temperature | (μm/ |
| Composition | Water:Composition | (minutes) | (° C.) | side) |
| 6 | 40:1 | 5 | 30 | <0.005 |
| 6 | 40:1 | 5 | 50 | 0.006 |
| 7 | 40:1 | 5 | 50 | <0.005 |
| 7 | 80:1 | 5 | 70 | <0.005 |
| 8 | 40:1 | 5 | 50 | <0.005 |
| 8 | 60:1 | 1 | 70 | <0.005 |
| 4 | 40:1 | 5 | 50 | <0.005 |
| 4 | 80:1 | 5 | 70 | 0.006 |
| 9 | 40:1 | 30 | 40 | 0.03 |
| 11 | 40:1 | 30 | 40 | 0.04 |
| 12 | 40:1 | 30 | 40 | 0.04 |
| 13 | 40:1 | 30 | 40 | <0.005 |
| 14 | 40:1 | 30 | 40 | 0.02 |
| 15 | 40:1 | 30 | 40 | 0.009 |

### Example 8

### Enhanced Silicon Removal

If additional silicon removal is desired, this can be achieved by changing some or all of the treatment variables dilution, temperature and time used for the conditioning treatment. Such additional silicon removal might be used to remove a layer of saw-damaged silicon from the surface before texturing or to strip the chemical oxide that remains on the silicon surface after texturing. Treatment conditions useful for removing additional silicon are demonstrated in Table VI.

TABLE VI

| | | | | Silicon |
|---|---|---|---|---|
| | | Conditioning | Conditioning | Loss |
| | Dilution Factor | Time | Temperature | (μm/ |
| Composition | Water:Composition | (minutes) | (° C.) | side) |
| 1 | 80:1 | 10 | 70 | 0.6 |
| 1 | 1:1 | 20 | 70 | 7.2 |
| 1 | 40:1 | 20 | 50 | 1.1 |
| 1 | 80:1 | 20 | 70 | 2.2 |
| 6 | 40:1 | 10 | 50 | 0.13 |
| 7 | 40:1 | 5 | 70 | 0.3 |
| 7 | 40:1 | 1 | 70 | 0.3 |
| 8 | 1:1 | 20 | 70 | 7.6 |
| 8 | 40:1 | 20 | 70 | 3.2 |
| 8 | 60:1 | 5 | 70 | 0.3 |
| 10 | 40:1 | 30 | 40 | 0.1 |

### Example 9

### Removal of Transition Metal Surface Contamination

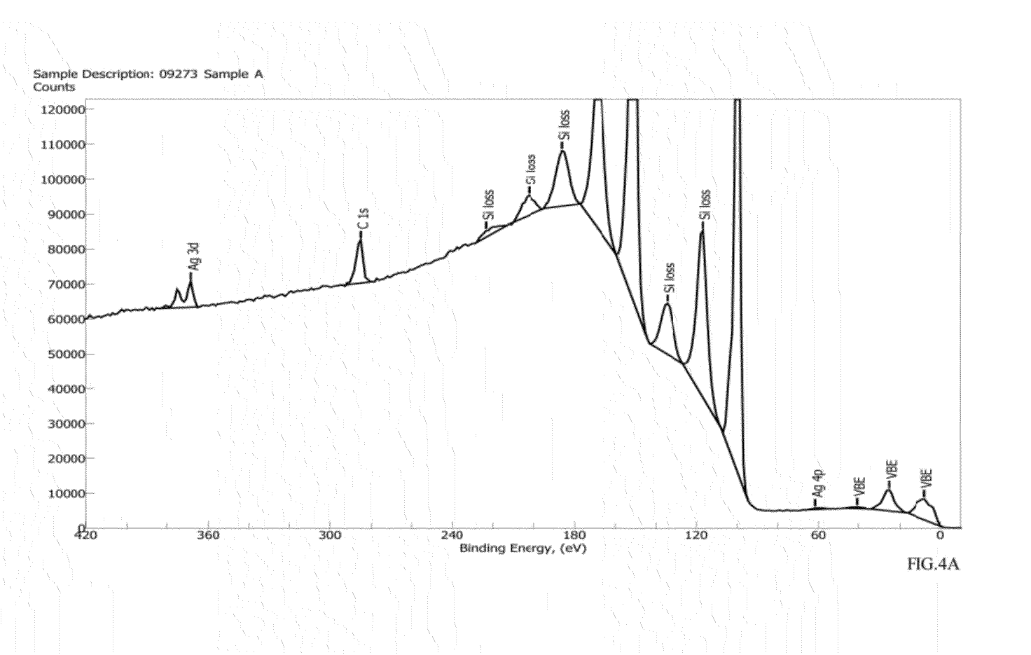

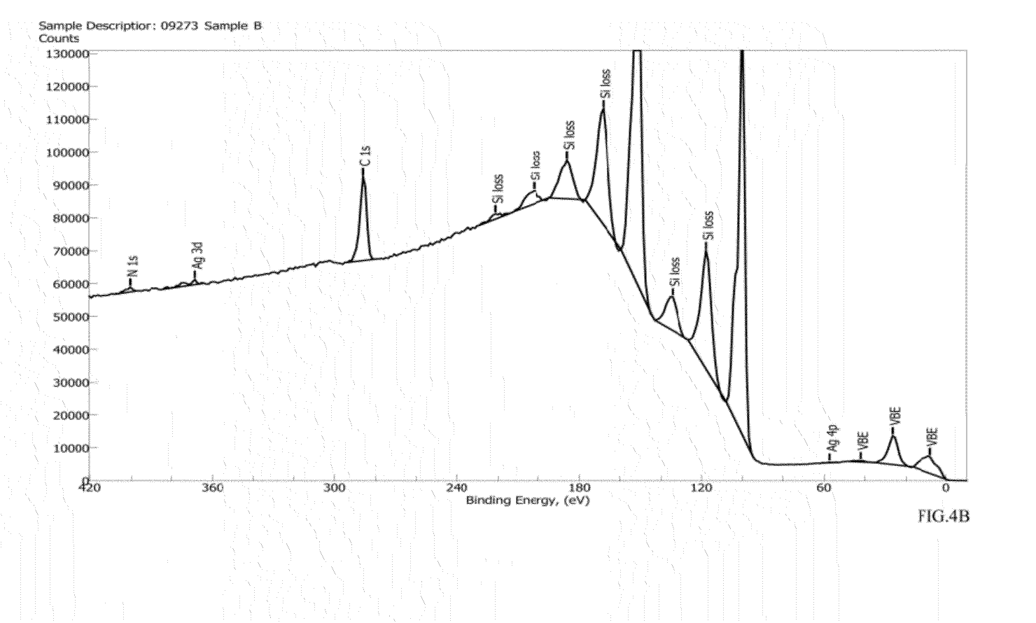

A production sample of photovoltaic silicon, contaminated with the transition metal silver, was conditioned with a solution of Composition 1 diluted 40:1 with water. FIG. 4A is a partial K-Alpha X-Ray Photoelectron Spectrum (XPS Spectrum) obtained from this contaminated sample. The presence of silver is clearly indicated by the Ag 3d peaks observed at a binding energy of 360-380 eV. FIG. 4B is a similar silicon sample after treatment with the dilute composition 1. A dramatic reduction of the Ag 3d contamination peaks was observed.

### Example 10

### Texturing of Wafer Surface

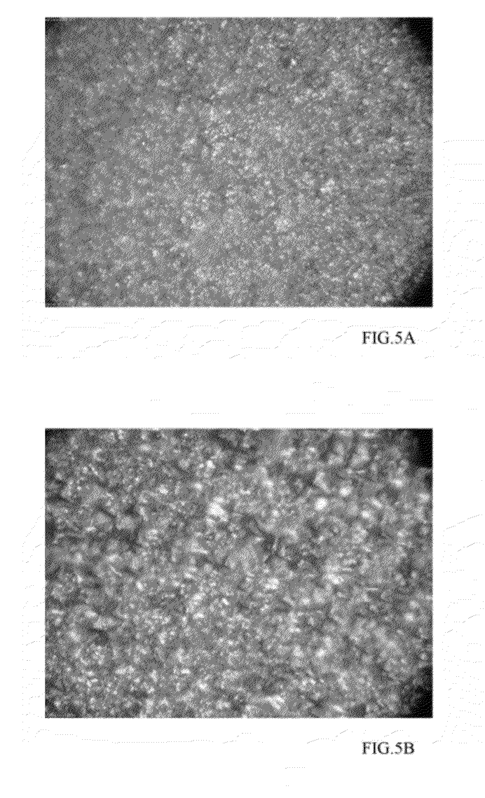

An unpolished silicon [100] wafer piece, typical of those used for manufacturing photovoltaic devices, was treated with Composition 1 diluted 1:1 with water and heated at 80° C. for 25 minutes while stirring at about 400 rpm. Hydrogen evolution commenced at approximately 3 minutes indicative of rapid silicon dissolution. The wafer piece was rinsed with water, dried, and examined using an optical microscope. FIG. 5A is an optical photomicrograph of the surface of the silicon used before texturing. FIG. 5B is an optical photomicrograph of the surface after the treatment described above. Pyramidal structures are clearly present after treatment verifying that texturing has occurred.

1. A composition for removing particles, organic contamination, and unwanted metals from silicon surfaces during the manufacture of photovoltaic devices using liquid compositions comprising one or more water soluble strongly basic components, one or more water soluble organic amines, one or more chelating agents, and water wherein the pH of the composition is from about 10 to 13.

2. A composition for removing particles, organic contamination, and unwanted metals from silicon surfaces during the manufacture of photovoltaic devices using liquid compositions comprising 0.001 to 5% by weight of water soluble strong base, 0.002 to 15% by weight water soluble organic amine, 0.001 to 4% by weight chelating agent, balance water wherein the pH of the composition is from about 10 to 13.

3. A composition according to claim 1 where the liquid compositions comprise 0.01 to 2.5% by weight of water soluble strong base, 0.05 to 10% by weight water soluble organic amine, 0.01 to 2% by weight chelating agent, balance water.

4. A composition according to claim 1 wherein the base is selected from the group consisting of potassium hydroxide, sodium hydroxide, tetramethyl ammonium hydroxide, tetraethyl ammonium hydroxide, benzyltrimethyl ammonium hydroxide, trimethyl-2-hydroxyethyl ammonium hydroxide (choline), trimethyl-3-hydroxypropyl ammonium hydroxide, trimethyl-3-hydroxybutyl ammonium hydroxide, trimethyl-4-hydroxybutyl ammonium hydroxide, triethyl-2-hydroxyethyl ammonium hydroxide, tripropyl-2-hydroxyethyl ammonium hydroxide, tributyl-2-hydroxyethyl ammonium hydroxide, dimethylethyl-2-hydroxyethyl ammonium hydroxide, dimethyldi(2-hydroxyethyl) ammonium hydroxide, monomethyltri(2-hydroxyethyl) ammonium hydroxide, tetrabutyl ammonium hydroxide, tetrapropyl ammonium hydroxide, monomethyltriethyl ammonium hydroxide, monomethyltripropyl ammonium hydroxide, monomethyltributyl ammonium hydroxide, monoethyltrimethyl ammonium hydroxide, monoethyltributyl ammonium hydroxide, and mixtures thereof, the water soluble amine is selected from the group 2-aminoethanol, 2-dimethylaminoethanol, 1-amino-2-propanol, 1-amino-3-propanol, 2-(2-aminoethoxy)ethanol, 2-methylaminoethanol, 2-(2-aminoethylamino)ethanol, 4-(3-aminopropyl)morpholine, diethanolamine, triethanolamine, guanidine, 1,3-pentanediamine, 4-aminomethyl-1,8-octanediamine, 2-aminoethylpiperazine, 2-(2-aminoethylamino)ethylamine, 1,2-diaminocyclohexane, tris(2-aminoethyl)amine, and 2-methyl-1,5-pentanediamine, and mixtures thereof, and the chelating agent is selected from the group ethylenediaminetetraacetic acid (EDTA), butylenediaminetetraacetic acid, 1,2-cyclohexanediamine-N,N,N′,N′-tetraacetic acid (CyDTA), diethylenetriaminepentaacetic acid (DETPA), ethylenediaminetetraproprionic acid, (hydroxyl)ethylenediaminetriacetic acid (HEDTA), N,N,N′,N′-ethylenediaminetetra(methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrilotriacetic acid (NTA), citric acid, tartaric acid, gluconic acid, saccharic acid, glyceric acid, phthalic acid, maleic acid, mandelic acid, malonic acid, lactic acid, salicylic acid, cystine, and mixtures thereof.

5. A composition according to claim 1 wherein the base is selected from the group consisting of tetramethyl ammonium hydroxide, tetraethyl ammonium hydroxide and potassium hydroxide and mixtures thereof.

6. A composition according to claim 1 wherein the amine is an alkanolamine.

7. A composition according to claim 1 wherein the amine is 2-aminoethanol.

8. A composition according to claim 1 where the chelating agent is selected from the group ethylenediaminetetraacetic acid and 1,2-diaminocyclohexane-N,N,N′,N′-tetraacetic acid.

9. A composition according to claim 1 wherein the base is selected from the group consisting of potassium hydroxide, tetramethyl ammonium hydroxide, and tetraethyl ammonium hydroxide, the water soluble amine is 2-aminoethanol, and the chelating agent is selected from the group ethylenediaminetetraacetic acid (EDTA) and 1,2-cyclohexanediamine-N,N,N′,N′-tetraacetic acid (CyDTA).

10. A composition for removing a thin layer of silicon from or texturing a silicon surface during the manufacture of photovoltaic devices using liquid compositions comprising one or more water soluble strongly basic components capable of producing a pH greater than 10, one or more water soluble organic amines, one or more chelating agents, and water.

11. A composition for removing a thin layer of silicon from or texturing a silicon surface during the manufacture of photovoltaic devices comprising 0.001 to 5% by weight of water soluble strong base, 0.002 to 15% by weight water soluble organic amine, 0.001 to 4% by weight chelating agent, balance water wherein the pH of the composition is from about 10 to 13.

12. A composition according to claim 11 where the liquid compositions comprise 0.01 to 2.5% by weight of water soluble strong base, 0.05 to 10% by weight water soluble organic amine, 0.01 to 2% by weight chelating agent, balance water.

13. A composition according to claim 11 wherein the base is selected from the group consisting of potassium hydroxide, sodium hydroxide, tetramethyl ammonium hydroxide, tetraethyl ammonium hydroxide, benzyltrimethyl ammonium hydroxide, trimethyl-2-hydroxyethyl ammonium hydroxide (choline), trimethyl-3-hydroxypropyl ammonium hydroxide, trimethyl-3-hydroxybutyl ammonium hydroxide, trimethyl-4-hydroxybutyl ammonium hydroxide, triethyl-2-hydroxyethyl ammonium hydroxide, tripropyl-2-hydroxyethyl ammonium hydroxide, tributyl-2-hydroxyethyl ammonium hydroxide, dimethylethyl-2-hydroxyethyl ammonium hydroxide, dimethyldi(2-hydroxyethyl) ammonium hydroxide, monomethyltri(2-hydroxyethyl) ammonium hydroxide, tetrabutyl ammonium hydroxide, tetrapropyl ammonium hydroxide, monomethyltriethyl ammonium hydroxide, monomethyltripropyl ammonium hydroxide, monomethyltributyl ammonium hydroxide, monoethyltrimethyl ammonium hydroxide, monoethyltributyl ammonium hydroxide, and mixtures thereof, the water soluble amine is selected from the group 2-aminoethanol, 2-dimethylaminoethanol, 1-amino-2-propanol, 1-amino-3-propanol, 2-(2-aminoethoxy)ethanol, 2-methylaminoethanol, 2-(2-aminoethylamino)ethanol, 4-(3-aminopropyl)morpholine, diethanolamine, triethanolamine, guanidine, 1,3-pentanediamine, 4-aminomethyl-1,8-octanediamine, 2-aminoethylpiperazine, 2-(2-aminoethylamino)ethylamine, 1,2-diaminocyclohexane, tris(2-aminoethyl)amine, and 2-methyl-1,5-pentanediamine, and mixtures thereof, and the chelating agent is selected from the group ethylenediaminetetraacetic acid (EDTA), butylenediaminetetraacetic acid, 1,2-cyclohexanediamine-N,N,N′,N′-tetraacetic acid (CyDTA), diethylenetriaminepentaacetic acid (DETPA), ethylenediaminetetraproprionic acid, (hydroxyl)ethylenediaminetriacetic acid (HEDTA), N,N,N′,N′-ethylenediaminetetra(methylenephosphonic) acid (EDTMP), triethylenetetraminehexaacetic acid (TTHA), 1,3-diamino-2-hydroxypropane-N,N,N′,N′-tetraacetic acid (DHPTA), methyliminodiacetic acid, propylenediaminetetraacetic acid, nitrilotriacetic acid (NTA), citric acid, tartaric acid, gluconic acid, saccharic acid, glyceric acid, phthalic acid, maleic acid, mandelic acid, malonic acid, lactic acid, salicylic acid, cystine, and mixtures thereof.

14. A composition according to claim 11 where the base is selected from the group consisting of tetramethylammonium hydroxide, tetraethylammonium hydroxide and potassium hydroxide and mixtures thereof.

15. A composition according to claim 11 where the amine is an alkanolamine.

16. A composition according to claim 11 where the amine is 2-aminoethanol.

17. A composition according to claim 11 where the chelating agent is selected from the group ethylenediaminetetraacetic acid and 1,2-diaminocyclohexanediamine-N,N,N′,N′-tetraacetic acid.

18. A composition according to claim 11 where the water soluble strong base produces a pH of about 10 to 12.

19. A composition according to claim 11 wherein the base is selected from the group consisting of potassium hydroxide, tetramethyl ammonium hydroxide, and tetraethyl ammonium hydroxide, the water soluble amine is 2-aminoethanol, and the chelating agent is selected from the group ethylenediaminetetraacetic acid (EDTA) and 1,2-cyclohexanediamine-N,N,N′,N′-tetraacetic acid (CyDTA).

20. A method for removing particles, organic contamination, and unwanted metals from silicon surfaces during the manufacture of photovoltaic devices comprising the steps of: preparing a liquid composition comprising one or more water soluble strongly basic components, one or more water soluble organic amines, one or more chelating agents, and water wherein the pH of the composition is from about 10 to 13, heating the composition to between 10° C. and 75° C., exposing the silicon surface to the liquid composition at temperature for from 1 to 30 minutes, and rinsing the silicon surface.

21. A method for removing particles, organic contamination, and unwanted metals from silicon surfaces during the manufacture of photovoltaic devices using liquid composition, the steps of preparing said composition to contain 0.001 to 5% by weight of water soluble strong base, 0.002 to 15% by weight water soluble organic amine, 0.001 to 4% by weight chelating agent, balance water wherein the pH of the composition is from about 10 to 13, heating the composition to between 10° C. and 75° C., exposing the silicon surface to the liquid composition at temperature for from 1 to 30 minutes, and rinsing the silicon surface.

22. A method according to claim 20 including the step of applying ultrasonic energy to said composition

23. A method according to claim 20 including the step of preparing the composition to contain 0.01 to 2.5% by weight of water soluble strong base, 0.05 to 10% by weight water soluble organic amine, 0.01 to 2% by weight chelating agent, balance water

24. A method for removing a thin layer of silicon from or texturing a silicon surface during the manufacture of photovoltaic devices comprising the steps of: preparing a liquid composition comprising 0.001 to 5% by weight of water soluble strong base, 0.002 to 15% by weight water soluble organic amine, 0.001 to 4% by weight chelating agent, balance water wherein the pH of the composition is from about 10 to 13, heating said composition to between 50° C. and 85° C., exposing said photovoltaic device to said heated solution for between 1 minute and 60 minutes, and rinsing said device.

25. A method according to claim 24 including the step of preparing the composition to contain 0.01 to 2.5% by weight of water soluble strong base, 0.05 to 10% by weight water soluble organic amine, 0.01 to 2% by weight chelating agent, balance water.
